(19) United States
(12) Patent Application Publication
(10) Pub. No.: US 2013/0019920 A1
(43) Pub. Date: Jan. 24, 2013

(54) COMBINATION SOLAR CELL SUN SENSOR FOR DIRECT ALIGNMENT OF TRACKERS AND CLOSED-LOOP TRACKING

(71) Applicant: Geoffrey S. Kinsey, Long Beach, CA (US)

(72) Inventor: Geoffrey S. Kinsey, Long Beach, CA (US)

(73) Assignee: AMONIX, INC., Seal Beach, CA (US)

(21) Appl. No.: 13/186,369

(22) Filed: Jul. 19, 2011

(51) Int. Cl. H01L 31/052; G01J 1/42

(52) U.S. Cl. 136/246; 250/208.2

(57) ABSTRACT

Apparatus and methods are described including an individual solar power generating and sun sensing cell formed to have a plurality of electrically isolated portions, the output of each portion being monitored and analyzed to determine whether the solar cell is optimally positioned relative to the direction of solar rays to optimize power generation of the solar cell, and also of an array of solar cells which includes the solar power generating and sun sensing cell.

### BACKGROUND

This invention is directed generally to apparatus and methods for locating and tracking a light source. More specifically, the present invention is directed to a system and method for optimizing the power generation of a photovoltaic power panel or array by utilizing a photovoltaic cell as both a power source and a solar tracking mechanism.

In concentrating photovoltaic (CPV) systems, optics are used to concentrate sunlight onto a relatively small solar cell. A primary optical element (such as a Fresnel lens) is used to concentrate the sunlight into a small spot on the aperture area of a solar cell. Typically, a tracking system is used to keep the spot of concentrated sunlight focused on the solar cell throughout the day.

In high-concentration CPV, where the concentration provided by the primary optical element is greater than 100x, a tracking system involving moving the photovoltaic panel or module in two-axes is used to keep the optical and cell surfaces perpendicular to the sun's rays during operation. Precise tracking, with a precision error of less than one degree is typically required in such systems to keep the spot centered on the cell area.

Tracking methods used to maintain the focused sun spot centered on the cell are generally divided into two methods: “open-loop” tracking, in which the system is pointed in a direction where the sun is expected to be, based on geographical location and the time of year, and “closed-loop” tracking, in which the location of the sun is determined by measuring its intensity and providing feedback to the tracker to allow it to follow the sun's apparent motion across the sky. Open-loop and closed-loop methods might be used separately, or they may be combined in larger systems. For CPV, some form of “closed-loop” tracking is required in order to achieve the necessary precision.

Generally some form of “closed-loop” tracking is required for the tracking precision necessary to optimize power generation in a CPV system. Closed-loop tracking systems utilize a sensor to detect the sun's position and align the system accordingly. For small systems, the sensor is may often be the photovoltaic module itself In such systems, the output of the module is connected to a monitoring system, such as computer or processor programmed with software designed to monitor the power output of the module. The processor typically applies a “perturb and observe” algorithm to the system. Using such an algorithm, the processor changes the position of the module slightly and evaluates the change in the power output of the module. The processor continues to cause the module to move in the direction of higher power output until the peak power is obtained. This is a form of maximum power point tracking (MPPT). While such a system is useful for small photovoltaic systems, it requires use of power to initiate movement of the module, and thus reduces the net power output of the module. Moreover, such a system is often inefficient when applied to a larger system, since it may be difficult to maximize the power of a large array.

For larger systems, an independent sun sensor is often used. Such a sun sensor measures the misalignment between the sun's rays and the system and moves the system to minimize the misalignment. One example of such a sun sensor is a quadrant sun sensor. Light falling on each quadrant generates electric current proportional to the intensity of sunlight. The current output by each quadrant of the sensor is measured; and when the current from each quadrant is equal, the sun is centered on the sensor. If the sensor is aligned with the system, then the system will also be aligned properly.

Until recently, both types of “closed-loop” tracking described above have suffered from significant limitations. For example, the modules employing such closed-loop systems must be aligned properly to the tracker mechanism during installation of the module. This process can be difficult, time consuming, and prone to error.

Another problems is that, once the modules are aligned and operating, the “perturb and observe” approach often results in a measurable decrease in power output before the monitoring software can detect an off-track condition and begin moving the system back into alignment. The frequent movement, or perturbation, of the system to “observe” the changes also results in significant power consumption in a system that is meant to produce, not consume, power. For these reasons, the “perturb and observe” method of closed-loop tracking is an unacceptable option for large systems where even small movements off track cause significant power losses, and which also require more power to move.

While the use of an independent sun sensor can eliminate the issues described above with respect to the “perturb and observer” approach, the use of a separate sun sensor presents difficulties of its own. For example, the use of a separate sensor unit adds cost and complexity to the system; moreover, the reliability of the sun sensor may require frequent maintenance or replacement.

Importantly, since the sensor output is independent of the system's generating power, there is no guarantee that the alignment of the sun sensor with the sun corresponds to alignment of the adjacent power modules to the sun. Accordingly, the sun sensor must be carefully aligned with the power module for the sun sensor to be effective in maximizing the power generation of the module. Delicate and time-consuming calibration of the sun sensor is required during installation, and ongoing maintenance is necessary to verify that proper alignment is maintained. For large systems involving many panels, there may also be significant variation in both the alignment and power output of each of the panels. Thus, it may become difficult to determine which alignment will provide the most overall system power and energy.

What has been needed, and heretofore unavailable, is a simple to install and calibrate, reliable and low cost system and method for aligning a large, high concentrating photovoltaic system. Such a system would provide reliable, precise tracking of the sun to maximize power generation by the system while minimizing power losses due to parasitic power consumption. The present invention satisfies these and other needs.

### SUMMARY OF THE INVENTION

In its most general aspect, the present invention includes a specially modified power generating solar cell that includes two or more electrically isolated portions, with each portion capable of being independently monitored. The output generated by each independently monitored portion is analyzed to determine if the power generated by each portion is substantially equal, and if not, algorithms are applied that result in a processor or controller providing positioning signals to a mechanism designed to move an array of solar cells that includes the specially modified power generating solar cell into optimal alignment with the direction light rays incident on the cell from the sun.

In another aspect, the present invention includes a sun sensor configured to provide an indication of the position of the sun, comprising: a solar cell disposed on a moveable structure, the solar cell configured to have a plurality of electrical current generating portions; a plurality of electrical contacts, each of the plurality of electrical contacts configured to tap a signal generated by an individual electrical current generating portion of the solar cell; a plurality of electrical parameter monitors, each of the plurality of electrical parameter monitors in electrical communication with one of the plurality of electrical contacts, and each of the electrical parameter monitors configured to provide a signal representative of an electrical parameter generated by one of the plurality of electrical current generating portions of the solar cell. In an one aspect, the electrical parameter is a current; in another aspect, the electrical parameter is a voltage.

In yet another aspect, each of the plurality of power generating portions of the solar cell are separated from each other by an area having electrical resistance sufficient to electrically isolate each of the plurality of power generating portions of the solar cell from each other.

In still another aspect, the area of electrical resistance is a trench formed in a layer of the solar cell.

In yet another aspect, the solar cell is formed from a light absorbing electrical current generating semiconductor material disposed on an electrically insulated substrate. In a still further aspect, the plurality of electrical current generating portions are defined by electrically isolating separators disposed in the light absorbing electrical current generating semiconductor material to divide the light absorbing electrical current generating semiconductor material into the plurality of electrical current generating portions. In another aspect, an individual one of the plurality of electrical contacts is in electrical communication with an individual one of the plurality of electrical current generating portions.

In a still further aspect, the separator is formed by removing a portion of the light absorbing electrical current generating semiconductor material to define an electrically isolated portion of the light absorbing electrical current generating semiconductor material. In another aspect, the substrate is thermally conductive.

In yet another aspect, the present invention includes a sun sensor for tracking the location of the sun, comprising: a solar cell mounted on a moveable structure, the solar cell having a plurality of trenches that define electrically isolated electrical current generating portions of the solar cell; a plurality of electrical contacts, each one of the plurality of electrical contacts in electrical communication with a different electrically isolated electrical current generating portions of the solar cell; and a plurality of electrical parameter monitors, each of the plurality of electrical parameter monitors in electrical communication with one of the plurality of electrical contacts, and each of the electrical parameter monitors configured to provide a signal representative of an electrical parameter generated by one of the plurality of the electrically isolated electrical current generating portions of the solar cell. In one alternative aspect, the electrical parameter is a current.

In a further aspect, the present invention includes a sun sensor for use in controlling the movement of a photovoltaic array to maintain the alignment of the photovoltaic array with the sun as the sun moves across the sky during a day, comprising: a sun sensing solar cell mounted on an insulating substrate, the insulated substrate disposed on a moveable support structure as part of an array of power generating solar cells, the sun sensing solar cell having a plurality electrically isolated electrical current generating portions defined by areas of areas of increased electrical resistivity disposed between the plurality electrically isolated electrical current generating portions, the sun sensing solar cell also contributing to a power output of the array of power generating solar cells; a plurality of electrical contacts, each one of the plurality of electrical contacts in electrical communication with a different electrically isolated electrical current generating portion of the sun sensing solar cell; and a plurality of electrical parameter monitors, each of the plurality of electrical parameter monitors in electrical communication with one of the plurality of electrical contacts, and each of the electrical parameter monitors configured to provide a signal representative of an electrical parameter generated by one of the plurality of the electrically isolated electrical current generating portions of the sun sensing solar cell.

In yet another aspect, the present invention further comprises a processor configured to receive the signals from the plurality of the electrical parameter monitors and also configured to analyze those signals and to provide appropriate control signals to the moveable structure to position the solar cell in relation to the sun so as to substantially equalize the electrical parameter generated by each of the electrically isolated electrical current generating portions of the solar cell.

In still another aspect, the present invention includes a sun sensor for use in controlling the movement of a photovoltaic array to maintain the alignment of the photovoltaic array with the sun as the sun moves across the sky during a day, comprising: a sun sensing solar cell mounted on an insulating substrate, the insulated substrate disposed on a moveable support structure as part of an array of power generating solar cells, the sun sensing solar cell having a plurality electrically isolated electrical current generating portions defined by areas of areas of increased electrical resistivity disposed between the plurality electrically isolated electrical current generating portions, the sun sensing solar cell also contributing to a power output of the array of power generating solar cells.

In yet another aspect, the present invention includes a sun sensor configured to provide an indication of the position of the sun, comprising: a solar cell disposed on a moveable structure, the solar cell configured to have a plurality of electrical current generating portions; a plurality of electrical contacts, each of the plurality of electrical contacts configured to tap a signal generated by an individual electrical current generating portion of the solar cell; a plurality of electrical parameter monitors, each of the plurality of electrical parameter monitors in electrical communication with one of the plurality of electrical contacts, and each of the electrical parameter monitors configured to provide a signal representative of an electrical parameter generated by one of the plurality of electrical current generating portions of the solar cell; and a processor configured to receive the signals from the plurality of the electrical parameter monitors and also configured to analyze those signals and to provide appropriate control signals to the moveable structure to position the solar cell in relation to the sun so as to substantially equalize the electrical parameter generated by each of the electrical current generating portions of the solar cell.

Other features and advantages of the invention will become apparent from the following detailed description, taken in conjunction with the accompanying drawings, which illustrate, by way of example, the features of the invention.

### BRIEF DESCRIPTION OF THE DRAWINGS

FIG. 1 is a cross-sectional view of a concentrating photovoltaic cell.

FIG. 2 is a top view of a plurality of the concentrating photovoltaic cells of FIG. 1 arranged in a module.

FIG. 3 is a perspective view of a plurality of photovoltaic arrays incorporating the module of FIG. 2.

FIG. 4 is a top view of an individual solar cell.

FIG. 5 is a cross-sectional view of the solar cell of FIG. 4 shown mounted on an insulating substrate.

FIG. 6 is top view of one embodiment of a sun sensing and power generating solar cell in accordance with the present invention.

FIG. 7 is a cross-sectional view of the sun sensing and power generating solar cell of FIG. 6.

FIG. 8 is a flow chart illustrating one embodiment of method that can be used incorporating the sun sensing and power generating solar cell of FIG. 6 to locate and track the sun as it moves across the sky.

FIG. 9 is a schematic diagram showing a spot of focused sunlight incident upon the sun sensing and power generating solar cell of FIG. 6.

FIG. 10 is a flow chart illustrating one embodiment of a process utilizing signals provided by the various portions of the sun sensing and power generating solar cell of FIG. 6 for tracking the sun as it moves across the sky.

### DETAILED DESCRIPTION OF THE PREFERRED EMBODIMENTS

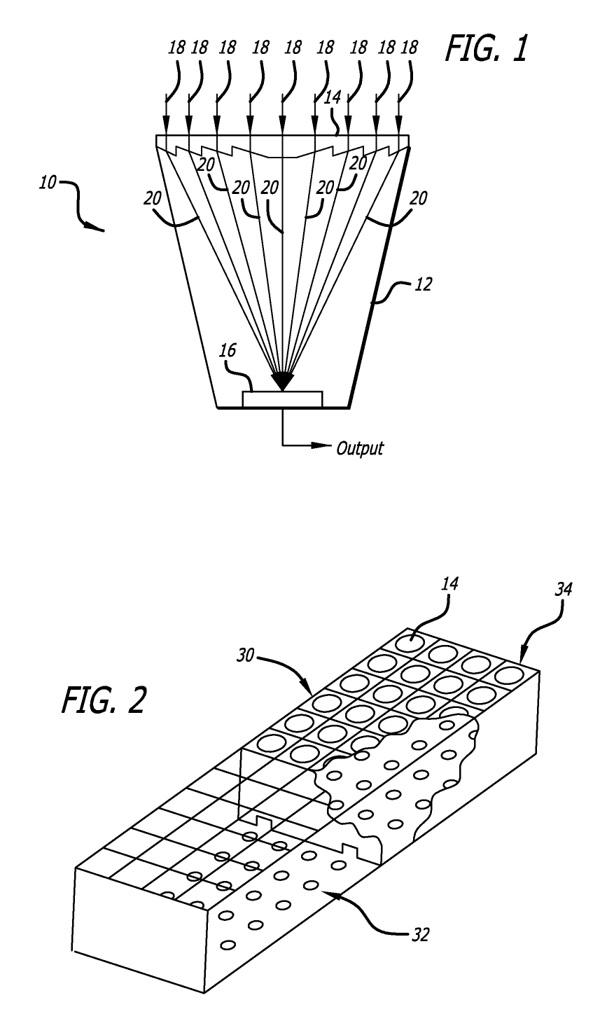

Referring now to the drawings in detail, in which like reference numerals indicate like or corresponding elements among the several figures, there is shown in FIG. 1 one embodiment of a high concentrating photovoltaic cell 10. Typically, a photovoltaic system would employ a large array, or module, containing a plurality of such photovoltaic cells. While the various embodiments of the invention will be described in relation to a high concentrating photovoltaic cell system, it will be immediately apparent that the embodiments of the inventions may be applied other types of photovoltaic systems where it is desirable to maximize power generation through precise positioning of the photovoltaic system while minimizing parasitic power losses due to the tracking system and method used.

High concentrating photovoltaic cell 10 typically has a housing 12 having sides that are sloping and/or reflective to assisting in focusing solar radiation or rays 18 onto a solar cell 16. Such a high concentrating cell 10 also includes a primary optical element 14, which may be, in some embodiments, a Fresnel lens. As shown in FIG. 1, solar rays 18 falling upon the primary optical element 14 are focused by element 14 onto the solar cell 16.

FIG. 2 is top view of a high concentrating photovoltaic power module 30. Such a power module typically has a plurality of high concentrating photovoltaic cells 32 mounted on a framework or assembly 34. Such an assembly is typically very stiff to ensure that the assembly may be moved in multiple axes to follow the movement of the sun across the sky to keep the solar rays focused on the solar cell of each photovoltaic cell 32. Examples of such modules and structures are described, for example, U.S. Pat. No. 6,559,371, entitled “High-Concentration Photovoltaic Assembly for a Utility-Scale Power Generation System”, U.S. Pat. No. 6,248,949 entitled “Method of Manufacturing a Solar Cell Receiver Plate of a Concentrator Photovoltaic Array” and U.S. Pat. No. 7,877,937 entitled “High-Stiffness, Light Weigh Beam Structure”, the entirety of which are hereby incorporated by reference herein.

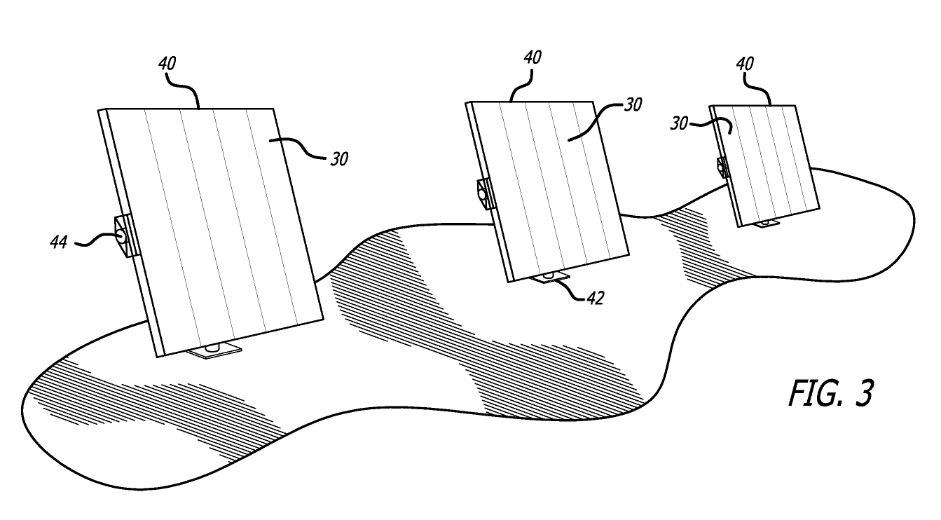

FIG. 3 is a perspective view showing a plurality of high concentrating modules 30 mounted in arrays 40 for the generation of power. As described above, the structure of the arrays 40 must also be sufficient robust to prevent deflection of the array, and thus the photovoltaic modules 30, that may be caused by gravity, wind or other factors, such as the accumulation of precipitation or dirt on the array structure. Such arrays are typically fixed in a Z-axis, often by mounting the array on a base 42, the bottom of which can be seen in FIG. 3. The array can then be moved in the X and Y axes by pivoting about a axle assembly 44 or rotating about the Z-axis. Those skilled in the art will appreciate the wide variety of mounting systems that can be used to provide the necessary translation and movement needed to focus the incoming solar rays onto the individual solar cells of the array or modules, and no attempt will be made here to describe such systems. The various embodiments of the present invention may be used with any such system that allows input from a computer or processor to move the array or module to focus the suns rays. One example of such a system is described in U.S. Pat. No. 6,123,067, entitled “Solar Collector Tracking System”, the entirety of which is hereby incorporated by reference herein.

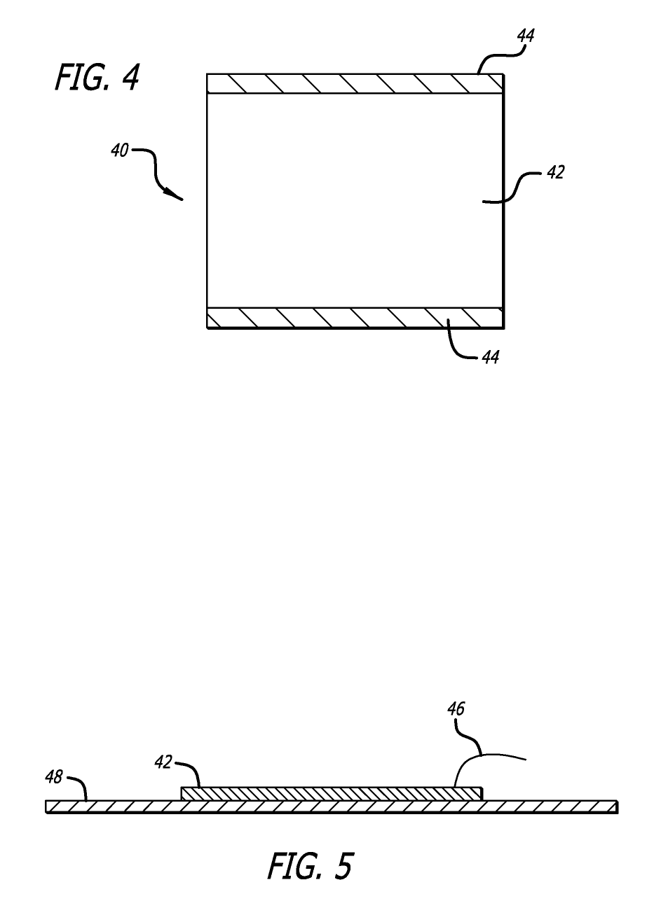

FIG. 4 is a top view of a typical solar cell 40 of the type used in the modules and arrays described above. Current is generated by sunlight focused upon the sunlight absorbing area 42 of the solar cell. The current is harvested from the sunlight absorbing are 42 using front-side electrical contacts 44. The current produced by solar cells used in power generating systems is typically on the order of five amperes, so the contacts 44 must be designed to withstand extraction of high currents without significant series resistance losses. Various types of solar cells exist that can be used with the various embodiments of the present invention, and are well known by those skilled in the art.

FIG. 5 is a cross-sectional view of the solar cell 40 illustrating how the light absorbing area 42 is mounted on a substrate for support. Typically, the cell is mounted on a ceramic substrate is electrically non-conductive and also resistant to the high temperatures commonly produced in a high concentrating photovoltaic cell. Electrical contact is made to the contacts 44 using a wire 46, interconnect tab, or ribbon bond.

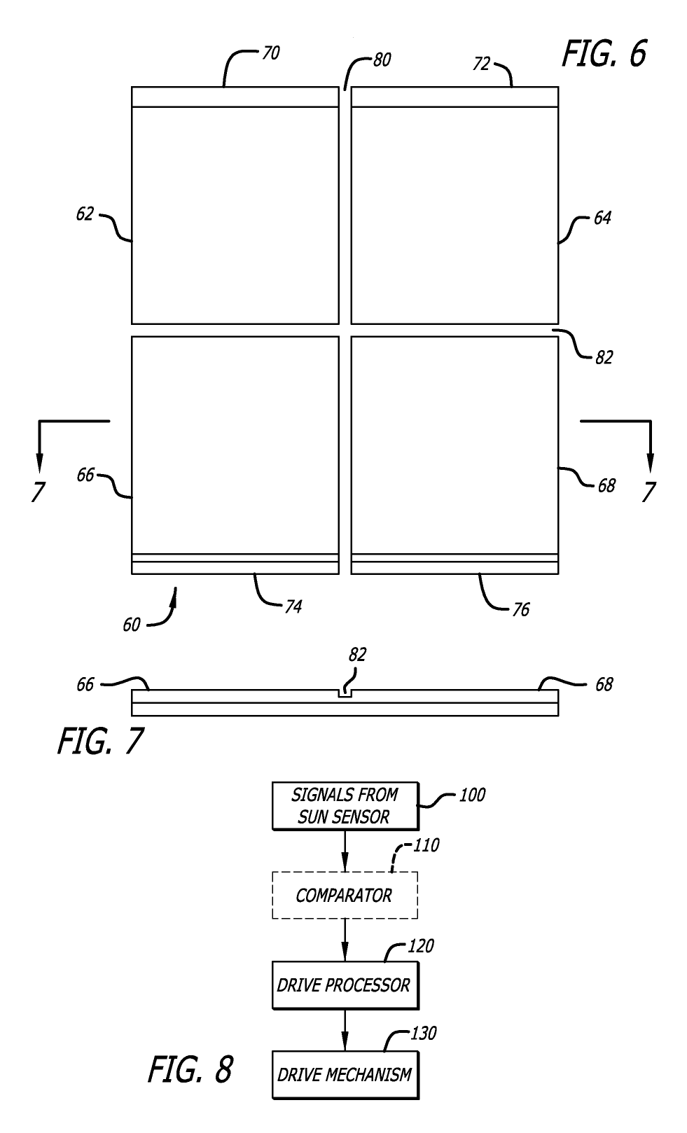

FIG. 6 is a top view of a solar cell 60 modified in accordance with one embodiment of the present invention. In this embodiment, solar cell 60 has been divided into quadrants 62, 64, 66, and 68, each with its own independent electrical contact 70, 72, 74 and 76 respectively. In this embodiment, each quadrant of solar cell 60 generates power. Moreover, each of quadrants 62, 64, 66, and 68 may be used as part of a sun sensor for detecting the position of the sun and providing an electrical signal that can be monitored by a suitably programmed computer or processor to determine whether the position of the cell, module or array needs to be modified to improve the focus of the sun's rays on the cell. For example, if the current of each quadrant is monitored, a higher current detected in quadrant 60 may indicate that the array in which the cell is mounted needs to be moved so that the current in each of quadrants 62, 64, 66, and 68 is equal.

A quadrant sun sensor in accordance with the various embodiments of the present invention may be introduced into a photovoltaic array or module without significant impact on the operation of the system. Those skilled in the art will recognize that a variety of techniques exist for manufacturing such a quadrant sun sensor solar cell. For example, the solar cell may be manufactured using current techniques, with electrical resistance increased between the quadrants by forming separators, such as, for example, narrow trenches 80, 82 into the cell to form the quadrants. Typical cell forming technology using photolithographic techniques, wet or dry chemical etching, laser scribing, and/or saw dicing may be used.

It is not necessary that the trenches penetrate the full thickness of the cell to provide sufficient isolation between the quadrants of the solar cell. For example, the depth of the trench may be less than the thickness of the top solar cell junction, that is, less than a few micrometers. For increased isolation between the quadrants, the trench may extend deeper into the thickness of the cell.

Where the semiconductor layers of the solar cell have high enough lateral resistance, it may only be necessary to provide the four separate contacts 70, 72, 74 and 76. In this embodiment, the relatively high lateral resistance minimizes “cross-talk” between adjacent quadrants. The relatively high lateral resistance between quadrants ensures that separate independent contacts 70, 72, 74 and 76 will provide sufficiently independent electrical signals to allow for sensor operation. If greater isolation is required, one or more of the previously described techniques may be used to separate the quadrants.

FIG. 7 is a cross-sectional view of the sun sensing power generating solar cell of FIG. 6 illustrating the formation of a trench 82 that provides increased lateral resistance between quadrants 66 and 68. As will be discussed below, the depth of trench 82 is determined by the amount of lateral resistance required to minimize cross-talk between adjacent quadrants.

Where a physical separation of quadrants 62, 64, 66, and 68 is required to ensure electrical isolation between the quadrants, the physical separation is typically in the range of 25 micrometers (μm) if a dicing saw is used to form the trenches between each quadrant. Where chemical etching is used to form the trenches, the trench width might be just a few micrometers in width. The depth of the trench may range from about 100 nanometers (nm) to approximately twenty percent (20%) of the cell thickness. For example, the trench formed in a 200 μm thick cell may be 40 μm deep. Typically, the depth of the trench will be selected to increase electrical isolation in part or all of the electrical junctions that comprise the various embodiments of the solar cell present invention. The resulting loss of power generating area of the solar cell caused by the formation of the trenches 80, 82 could be less than 0.5% of the total area of the cell, which is typically within the range of acceptable cell performance. If greater tracking precision is required, the power generating area of the solar cell may be further divided, or pixelated, to include more than four quadrants. Such an arrangement will continue to function without increasing the parasitic power demands on the cell where the monitoring technology used has low impedance, such as with an ammeter. Therefore, the sun sensor is enabled to simultaneously function as an integrated part of a power-generating solar array.

Returning now to FIG. 3, the mount 42 of a photovoltaic array may comprise various types of support structures. FIG. 3, for example, shows the module or array mounted on a pedestal-type mount. Generally, the mount 42 will include additional structure (not shown) such as set forth in U.S. Pat. No. 6,123,067 described above to enable movement of the module or array to permit the module or array 40 to point towards the sun. For example, the mount may be a two-axis mount that permits the array 40 to move around two orthogonal axes: an elevation (“X”) axis and a cross-elevation, or azimuth (“Y”) axis. Movement in the Y-axis permits the array 40 to move in a vertical plane from the horizon to ninety degrees, or directly, overhead. Movement in the X-axis permits the array 40 to move in a cross-elevation or azimuth along a horizontal plane from North, East, South, and West, depending on the range of movement allowed by the mechanical constraints of the structure.

A Y-axis drive mechanism may be used to automatically move the array 40 about the Y-axis. Similarly, an X-axis drive mechanism may be used to automatically move the array 40 about the X-axis. The drive mechanisms typically comprise drive motors mechanically coupled to drive gears or hydraulic actuators configured to rotate the array about the axes. In some embodiments, the drive motors are stepper motors or servo-motors, and the drive gears are worm gears. In other embodiments, the drives may be hydraulically actuated.

Generally, the drives are electrically coupled to a drive processor or computer that controls drive rates at which the array 40 rotates around each of the axes. The drive processor is configured to communicate drive signals to the drive mechanisms or actuators so as to control the pointing, tracking, and guiding of the array 40. For example, some embodiments of the drive mechanisms include position sensing devices such as, for example, rotary encoders for sensing the angular position of the axes. The rotary encoders may comprise mechanical, optical, or magnetic encoders. The drive processor may communicate drive signals through an electric connection such as a wire or may use wireless signals such as, for example, infrared or radio frequency signals.

Various embodiments of the drive processor may include electronic circuitry to control the drive mechanisms according to programming established to provide for sensing the position of the sun in relation to the pointing direction of the array 40, and then provide from movement of the array in the suitable axis or axes to optimize the power generation of the array. The drive processor may include a set of logic instructions for converting programming commands into electronic drive signals.

FIG. 8 is a flowchart illustrating an embodiment of a method that can be used to move the array 40 to track the sun to optimize power generation by the array. In block 100, a sun sensor receives light from the sun, and provides a signal, in this case, an output current. In the various embodiments described above, each quadrant of the sun sensor provides an independent signal to a comparator.

In block 110, the signals from the quadrant sensor may be communicated to an (optional) comparator by wired and/or wireless techniques. The wires that carry electrical power in the solar module or modules may also be used to carry the signals form the quadrant sensor. The wireless techniques may include transmitting and/or receiving electromagnetic signals, such as, for example, infrared or radio frequency signals. In some embodiments, the comparator comprises a microprocessor that implements a set of logic instructions for processing and/or analyzing the signals from the quadrant sensor. The logic instructions used by the comparator may be encoded in hardware, firmware, or software. The logic instructions may implement algorithms that use information from the signals to estimate parameters relating to the solar cell or individual quadrants of the solar sensor. For example, the parameters may include one or more of a current, voltage, power, brightness, flux, fluence, intensity, or other aspect relating to the sensor. Typically the parameter estimated will be an electrical current.

In FIG. 7, Block 110 is illustrated in phantom lines, because a comparator is an optional element in a tracking system. For example, in certain embodiments, some or all of the functions of a comparator may be performed by other components in the system, such as, for example, by a drive processor, a central processing unit, a controller, or other suitable hardware, software, or firmware. In other embodiments, some or all of the functions of the comparator are performed remotely from the array 40, such as, for example, by a remote computer. In various embodiments that include a comparator, the comparator may be disposed within the quadrant sun sensor, a drive processor, one or more drive mechanisms, drive motors, or in other components of the array. In other embodiments, the comparator may be remote from the array such as, for example, by being located on a computer network.

In optional block 110, the comparator produces one or more signals indicative of the parameters relating to the sun sensor. For example, the comparator signals may represent the amount of current being produced by each of the quadrants 62, 64, 66, and 68 of the sun sensor.

In block 120, the comparator signals may be communicated to a drive processor. The drive processor may also receive signals from one or more drive mechanisms that are used to move the array 40 about one or more axes. For example, one or more encoders coupled to the array axes may communicate the angular position of the array axes to the drive processor. The drive processor may further process or analyze the signals received from different components in the sun sensor system. The drive processor may be separate from or integrated with the comparator, and either or both may be implemented in hardware, software, or firmware. In certain embodiments, the drive processor is disposed in or on the array. In other embodiments, the drive processor may be disposed remotely from the array, as described above with reference to the comparator.

In block 130, the drive processor communicates with the array drive mechanisms so as to move the array as needed. In some embodiments, the drive processor generates one or more signals that are communicated to drive actuators coupled to the axes of the array. The drive processor can communicate signals so as to cause the array to point toward the sun and/or to track the sun as it moves.

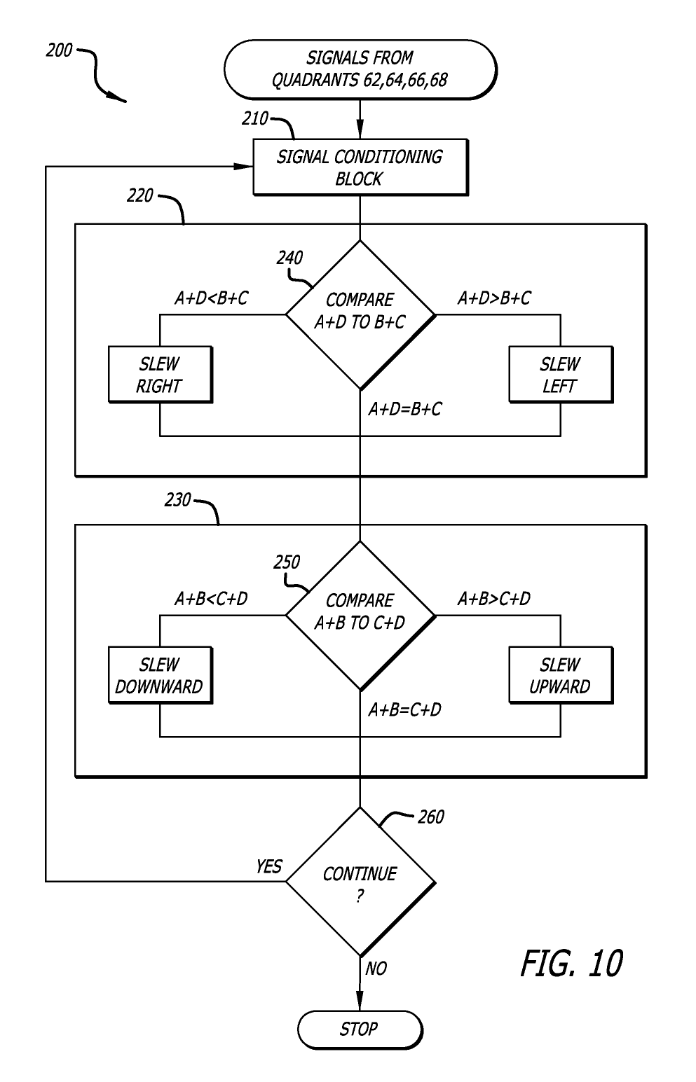

The flowchart illustrated in FIG. 8 is intended to be illustrative of one exemplary method for locating and tracking the sun and is not intended to be limiting. In other embodiments of locating and tracking methods, additional or fewer steps may be used, and the order in which the steps are performed may be different. The components shown in blocks 100-130 may be configured or arranged differently, and the components may implement additional, fewer, or different functions, methods, and processes. As discussed herein, block 110 is optional, and the functions of the comparator may be carried out by other components in the system. Other embodiments may combine the functions of the blocks in FIG. 10 and/or include additional or different blocks.

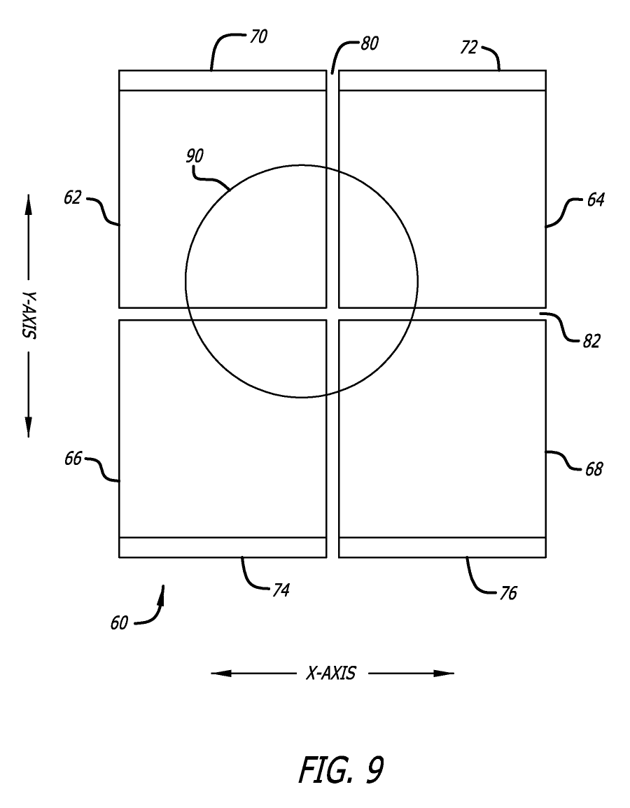

FIG. 9 is a schematic top view diagram of the quadrant sensor of FIG. 6 also showing the disposition of a spot of focused light 90 on the light absorbing areas of the quadrants of the sensor. In this embodiment, four quadrants 62, 64, 66, and 68 are shown, but this number is intended to be illustrative only and not limiting. Each of the four quadrants produce signals, such as an electrical current, in response to incident light, and the four signals will be denoted as A, B, C, and D referring to the current generated by quadrants, 64, 62, 66 and 68 respectively. In many embodiments, the signals are analog signals, such as, for example, currents or voltages; however, in some embodiments, the signals may be digital signals or a combination of analog and digital signals. The four quadrants 62, 64, 66, and 68 are arranged in a plane that is substantially perpendicular to an optical axis defined by the direction of the rays of the light of the sun.

In the various embodiments of the invention, the signals A, B, C, and D from the quadrants of the sensor are communicated to a comparator, as described above. The comparator is configured to use the signals to estimate a location and/or direction of the sun. As described previously, the comparator can communicate information relating to the sun's position to a drive processor and/or array drive mechanisms to move the array about the X and Y axes of the array in order to point to and/or track the sun.

FIG. 10 illustrates one embodiment of a flowchart describing a sample process 200 by which the signals A, B, C, and D generated by the quadrant sensor of FIG. 9 can be used to locate and track the sun. In this exemplary embodiment the process 200 comprises a signal conditioning code block 210, an X-axis tracking code block 220, and a Y-axis tracking code block 230. It will be understood that not all embodiments of the present invention will require a signal conditioning code block 210 to function, and that this feature is optional. In other embodiments, the process 200 may comprise more or fewer code blocks, which may be arranged and interconnected differently. The functions and procedures performed by the code blocks may be different, and the code blocks may implement different algorithms and procedures.

In an embodiment, process 200 may be implemented by a comparator such as that described in optional block 110 in FIG. 8. In other embodiments, some or all of the functions and code blocks illustrated in the process 200 may be carried out by different components of the system such as, for example, the drive processor or the array drive mechanisms. Many variations are possible, and FIG. 10 is intended as an illustrative, non-limiting embodiment of a process for locating and tracking the sun.

As used herein with reference to the description of FIG. 9, the phrase “code block” refers to logic embodied in hardware or firmware, or to a collection of software instructions, possibly having entry and exit points, written in a programming language, such as, for example, C, C++, Fortran, or Pascal.

A software code block may be compiled and linked into an executable program, installed in a dynamic link library, or may be written in an interpreted programming language. It will be appreciated that software code blocks may be callable from other code blocks or from themselves, and/or may be invoked in response to detected events or interrupts. The code blocks described herein are preferably implemented as software, but may be represented in hardware or firmware.

As shown in FIG. 10, one embodiment of the present invention may optionally include a signal conditioning code block 210 that receives the signals A, B, C, D from the quadrants 64, 62, 66, and 68 respectively (FIG. 9). Not all embodiments of the present invention will utilize the signal conditioning block, because the signals may already be in a form that is readily analyzed by the various code blocks of the process 200.

Additionally, the signals A, B, C, D may be converted from one electrical form to another, for example, a current may be converted to a voltage. In certain preferred embodiments, the signals A, B, C, and D are currents that may be amplified to enable more precise measurements. Some embodiments may utilize one or more amplifiers to convert the currents into measurable difference voltages.

The conditioned signals are communicated to the X-axis tracking code block 220 and the Y-axis tracking code block 230, which are configured to communicate output signals to the drive processor and/or the drive mechanisms to move the array. For example, the output signals may include instructions to move the array about a particular axis, in a particular direction, and at a particular rate. As described herein, X-axis directions such as “right” or “left,” and Y-axis directions such as “upward,” “above,” “downward,” or “below” are measured with respect to the plane of the quadrants 62, 64, 66, and 68 looking outward along the optical axis toward the sun.

FIG. 10 illustrates embodiments of algorithms that may be implemented by the X-axis and Y-axis tracking code blocks 220 and 230. In block 240 of the X-axis tracking code block 220, the sum of signals A and D are compared to the sum of the signals B and C. If the sum of signals A and D is greater than the sum of signals B and C, the sun is to the left of the optical axis, and the X-axis tracking code block 220 transmits an instruction to slew the array to the left. Conversely, if the sum of signals A and D is less than the sum of signals B and C, the sun is to the right of the optical axis, and the X-axis tracking code block 220 transmits an instruction to slew the array to the right. If the sum of signals A and D equals (to within a tolerance) the sum of signals B and C, no action is taken.

In block 250 of the Y-axis tracking code block 230, the sum of signals A and B are compared to the sum of the signals C and D. If the sum of signals A and B is greater than the sum of signals C and D, the sun is above the optical axis, and the Y-axis tracking code block 230 transmits an instruction to slew the array upward. Conversely, if the sum of signals A and B is less than the sum of signals C and D, the sun is below the optical axis, and the Y-axis tracking code block 230 transmits an instruction to slew the array downward. If the sum of signals A and B equals (to within a tolerance) the sum of signals C and D, no action is taken.

In block 260, an inquiry is made whether to continue to move the array. If the answer is yes, the process 200 loops back either to the signal conditioning code block 210, if used, or to the entry of code block 220 to receive further inputs from the quadrant sensors, and if the answer is no, the process 200 stops. In some embodiments, the process 200 may include code blocks configured to display information related to the inquiry on a screen, monitor, or other display, and which may be conveyed to a user audibly, tactilely, or visually. The user may input an answer to the inquiry via a keyboard, keypad, buttons, switches, or sensors. For example, the user may input a “stop” answer when the sun is located within the field of view of the array and the user has determined that the power generation of the array has been maximized. The user may also use the sun position information from the sun sensor to mechanically align the solar module with the sun.

In other embodiments, the process 200 may utilize a feedback loop to automate pointing the array toward the sun. For example, in certain embodiments, process 200 may repeat the procedures implemented in the code blocks 210, 220 and 230 until each of the signals A, B, C, and D is substantially equal to within an error tolerance. When the four signals are substantially equal, the sun has been located to within the error tolerance, and the array has been accurately pointed toward the sun to maximize the power generated by the array.

Returning again to FIG. 9, it is apparent that the spot of focused sun light 90 is not centered within the area of quadrant sensor 60, but is instead shining more on quadrant 62, approximately equally on quadrants 64 and 66, and least on quadrant 68. Thus, in order to maximize power generation of the array, the array should be slewed downwards and to the right to center spot 90 so that all of the quadrants 62, 64, 66 and 68 are receiving equal amounts of sun light, and thus are generating equal amounts of current.

In the example of FIG. 9, signal B generated by quadrant 62, which may be, for example, a current, will be greater than signals A and C (quadrants 64 and 66, respectively), which in turn are greater than signal D generated by quadrant 68. These signals are provided to the processor which may be running, for example, the process 200 as set forth in FIG. 10 and described above. Process 200 analyzes the signals A, B, C and D and provides the appropriate commands to the X-axis and Y-axis drive mechanisms that move the array to move the array downwards and to the right to center spot 90. The processor may monitor the signals from quadrant sensor 60 and continue to move the array in the appropriate direction until the monitored signals A-D are approximately equal, within a tolerance of error, or acceptable range. In some cases, the movement of the array may cause the array to overshoot the optimal position. In that case, the monitored signals A-D would not be equal, and the processor would again determine a desired movement of the array to obtain equality, and execute the movement. This process would continue until an acceptable position of the array with respect to the sun is achieved.

It will be apparent to those skilled in the art that the various embodiments of the present invention may also be used to point the array toward the sun, and then begin tracking the sun. This embodiment of the present invention is particularly useful at the beginning of a day. In some “open-loop” embodiments, the expected position of the sun at dawn of any given date and spatial local on earth can be stored in a memory associate with the processor charged with controlling the movement of the array. The system could, for example, turn off tracking of the sun at sun down, enter a hibernation state during the night to conserver power, and then, shortly before dawn, move the array into position to capture the first rays of the sun. Active or “closed-loop” monitoring would then begin to ensure optimal power generation by the array as the sun moves across the sky during the remainder of the day. Alternatively, an operator could enter appropriate coordinates for the array to position the array for the start of the day. A similar procedure may be used during initial installation of the array. In other embodiments, open-loop and closed-loop sun tracking may be combined.

After the array 40 (FIG. 3) is initially pointed toward the sun, the process 200 may be used to continue to monitor the signals from the quadrant sun sensor in order to track the motion of the sun and maintain alignment of the array with the sun to maximize power generation by the array. For example, if the sun moves away from the direction of the optical axis of the sun sensor 60, the signals A, B, C, and D will no longer be substantially equal. In response, the system will transmit signals to the X-axis and/or Y-axis drive mechanisms to re-center the sun onto the sun sensor 60. For example, in certain embodiments, the system implements a process similar to process 200 to track the sun.

In other embodiments present invention, the system may utilize algorithms and processes that are additional to and/or different from those illustrated in FIG. 10. For example, in some embodiments the signals A, B, C, and D may be combined to produce a coordinate location of the sun. In one such embodiment, Cartesian x-y coordinates may be determined from the signals generated by sensor 60 according to:

$$\begin{matrix}x = \frac{( A + D ) - ( B + C )}{A + B + C + D} \\ and & Equ . 1 \\ y = \frac{( A + B ) - ( C + D )}{A + B + C + D} & Equ . 2\end{matrix}$$

In this embodiment, the system transmits instructions to the drive processor or the drive mechanisms so as to reduce the coordinate values in Equations 1 and 2 to zero (within an error tolerance). The sun is located when the x-y coordinates are substantially equal to zero. Such an algorithm may be readily implemented in a feedback loop that monitors the x-y coordinates and makes adjustments to the X-axis and Y-axis drive mechanisms to ensure the x-y coordinates remain substantially equal to zero.

In other embodiments, the process 200 may include additional or different hardware or software code blocks than shown in the sample flowchart of FIG. 10. For example, the system may include other electronic circuits to implement other code blocks. For example, in some embodiments, the system may use a bridge circuit, such as a Wheatstone bridge, to determine when the four signals A, B, C, and D are substantially equal. As will be immediately apparent to those skilled in the art, many variations in logic and circuitry are possible, and are intended to be within the scope of the present invention.

The code blocks and functions of process 200 may be implemented in electronic circuitry comprising hardware, firmware, and/or software. The set of logic instructions implemented by the electronic circuitry may be embodied by a computer program that is executed by a processor or electronics as a series of computer- or control element-executable instructions. These instructions or data usable to generate these instructions may reside, for example, in random access memory (RAM), on a hard drive or optical drive, or on a disc.

A typical concentrating photovoltaic array contains hundreds of solar cells arranged into parallel and series strings in order to generate power. Sun sensors in accordance with the various aspects of the present invention are incorporated into the array of solar cells to provide sun position information. In general, the number of sun sensors deployed in each array could be relatively small, and their position among the solar cells of the array could be pre-determined, or could be placed according to an random assignment. Since the sun sensor cells are dispersed among the solar cells, the signals from the suns sensor cells may be useful in aligning and calibration of the array during installation of the array.

An additional advantage of the sun sensor/solar cells of the various embodiments of the present invention is that each of the sun sensor cells also generates power similar to an ordinary solar cell. Any loss in power from the sun sensor solar cells would be within the range of power generation variation expected from the operation of ordinary solar cells. Thus, there can be a large number of suns sensor cells dispersed in the array without decreasing the efficiency of the array. Further, not all of the sensor cells dispersed within the array would be needed to track the sun. This feature add redundancy and would allow the processor monitoring the sun sensor cells to be programmed to use only the number of cells necessary to adequately track the sun, ignoring the signals from the rest of the sensors. Should one or more of the monitored cells fail, the processor would simply begin actively monitoring a sun sensor cell or cells located in the approximate area of the failed cell. In some embodiments, every solar cell in the array could be a sun sensor/solar cell. In other embodiments, only a single sun sensor/solar cell might be incorporated into the array to provide sun tracking information to the processor control the tracking process.

While several particular forms of the invention have been illustrated and described, it will be apparent that various modifications can be made without departing from the spirit and scope of the invention.

We claim:

1. A sun sensor configured to provide an indication of the position of the sun, comprising:
a solar cell disposed on a moveable structure, the solar cell configured to have a plurality of electrical current generating portions;
a plurality of electrical contacts, each of the plurality of electrical contacts configured to tap a signal generated by an individual electrical current generating portion of the solar cell; and
a plurality of electrical parameter monitors, each of the plurality of electrical parameter monitors in electrical communication with one of the plurality of electrical contacts, and each of the electrical parameter monitors configured to provide a signal representative of an electrical parameter generated by one of the plurality of electrical current generating portions of the solar cell.

2. The sun sensor of claim 1, wherein the electrical parameter is a current.

3. The sun sensor of claim 1, wherein the electrical parameter is a voltage.

4. The sun sensor of claim 1, wherein each of the plurality of power generating portions of the solar cell are separated from each other by an area having electrical resistance sufficient to electrically isolate each of the plurality of power generating portions of the solar cell from each other.

5. The sun sensor of claim 4, wherein the area of electrical resistance is a trench formed in a layer of the solar cell.

6. The sun sensor of claim 1, wherein the solar cell is formed from a light absorbing electrical current generating semiconductor material disposed on an electrically insulated substrate.

7. The sun sensor of claim 6, wherein the plurality of electrical current generating portions are defined by electrically isolating separators disposed in the light absorbing electrical current generating semiconductor material to divide the light absorbing electrical current generating semiconductor material into the plurality of electrical current generating portions.

8. The sun sensor of claim 7, wherein an individual one of the plurality of electrical contacts is in electrical communication with an individual one of the plurality of electrical current generating portions.

9. The sun sensor of claim 7, wherein the separator is formed by removing a portion of the light absorbing electrical current generating semiconductor material to define an electrically isolated portion of the light absorbing electrical current generating semiconductor material.

10. The sun sensor of claim 4, wherein the substrate is thermally conductive.

11. A sun sensor for tracking the location of the sun, comprising:
a solar cell mounted on a moveable structure, the solar cell having a plurality of trenches that define electrically isolated electrical current generating portions of the solar cell;
a plurality of electrical contacts, each one of the plurality of electrical contacts in electrical communication with a different electrically isolated electrical current generating portions of the solar cell; and
a plurality of electrical parameter monitors, each of the plurality of electrical parameter monitors in electrical communication with one of the plurality of electrical contacts, and each of the electrical parameter monitors configured to provide a signal representative of an electrical parameter generated by one of the plurality of the electrically isolated electrical current generating portions of the solar cell.

12. The sun sensor of claim 11, wherein the electrical parameter is a current.

13. A sun sensor for use in controlling the movement of a photovoltaic array to maintain the alignment of the photovoltaic array with the sun as the sun moves across the sky during a day, comprising:
a sun sensing solar cell mounted on an insulating substrate, the insulated substrate disposed on a moveable support structure as part of an array of power generating solar cells, the sun sensing solar cell having a plurality electrically isolated electrical current generating portions defined by areas of areas of increased electrical resistivity disposed between the plurality electrically isolated electrical current generating portions, the sun sensing solar cell also contributing to a power output of the array of power generating solar cells;
a plurality of electrical contacts, each one of the plurality of electrical contacts in electrical communication with a different electrically isolated electrical current generating portion of the sun sensing solar cell; and
a plurality of electrical parameter monitors, each of the plurality of electrical parameter monitors in electrical communication with one of the plurality of electrical contacts, and each of the electrical parameter monitors configured to provide a signal representative of an electrical parameter generated by one of the plurality of the electrically isolated electrical current generating portions of the sun sensing solar cell.

14. The sun sensor of claim 13, further comprising a processor configured to receive the signals from the plurality of the electrical parameter monitors and also configured to analyze those signals and to provide appropriate control signals to the moveable structure to position the solar cell in relation to the sun so as to substantially equalize the electrical parameter generated by each of the electrically isolated electrical current generating portions of the solar cell.

15. A sun sensor for use in controlling the movement of a photovoltaic array to maintain the alignment of the photovoltaic array with the sun as the sun moves across the sky during a day, comprising:
a sun sensing solar cell mounted on an insulating substrate, the insulated substrate disposed on a moveable support structure as part of an array of power generating solar cells, the sun sensing solar cell having a plurality electrically isolated electrical current generating portions defined by areas of areas of increased electrical resistivity disposed between the plurality electrically isolated electrical current generating portions, the sun sensing solar cell also contributing to a power output of the array of power generating solar cells.

16. A sun sensor configured to provide an indication of the position of the sun, comprising:
a solar cell disposed on a moveable structure, the solar cell configured to have a plurality of electrical current generating portions;
a plurality of electrical contacts, each of the plurality of electrical contacts configured to tap a signal generated by an individual electrical current generating portion of the solar cell;
a plurality of electrical parameter monitors, each of the plurality of electrical parameter monitors in electrical communication with one of the plurality of electrical contacts, and each of the electrical parameter monitors configured to provide a signal representative of an electrical parameter generated by one of the plurality of electrical current generating portions of the solar cell; and
a processor configured to receive the signals from the plurality of the electrical parameter monitors and also configured to analyze those signals and to provide appropriate control signals to the moveable structure to position the solar cell in relation to the sun so as to substantially equalize the electrical parameter generated by each of the electrical current generating portions of the solar cell.
